(19) United States
(12) Patent Application Publication
(10) Pub. No.: US 2025/0369090 A1
(43) Pub. Date: Dec. 4, 2025

(54) DEPOSITION MASK AND DEPOSITION APPARATUS INCLUDING THE SAME

(71) Applicant: Samsung Display Co., LTD., Yongin-si (KR)

(72) Inventors: Jeong Kuk KIM, Yongin-si (KR); Duck Jung LEE, Yongin-si (KR); Sung Won CHO, Yongin-si (KR); Jun Ho JO, Yongin-si (KR)

(21) Appl. No.: 19/031,804

(22) Filed: Jan. 18, 2025

(30) Foreign Application Priority Data
May 30, 2024 (KR) 10-2024-0070838

(51) Int. Cl. C23C 14/04; H10K 59/12; H10K 71/16

(52) U.S. Cl. CPC C23C 14/042; H10K 59/1201; H10K 71/166

(57) ABSTRACT

A deposition mask includes a mask frame defining cell openings therein, and a membrane including mask cell regions disposed above and overlapping the cell openings, respectively, and a grid region disposed between the mask cell regions. A recess is defined at a surface portion of the membrane, and the mask frame includes a rib region defining the cell openings and a lower electrode disposed to be spaced apart from the recess in a thickness direction of the mask frame.

This application claims priority to Korean Patent Application No. 10-2024-0070838, filed on May 30, 2024, and all the benefits accruing therefrom under 35 U.S.C. § 119, the content of which in its entirety is herein incorporated by reference.

### BACKGROUND

### 1. Technical Field

The present disclosure relates to a deposition mask, a deposition apparatus including the same, and an electronic device manufactured by using the same.

### 2. Description of the Related Art

Wearable devices in which a focus is formed at a distance close to user's eyes have been developed in the form of glasses or a helmet. For example, the wearable device may be a head mounted display (“HMD”) device or AR glasses. The wearable device may provide an augmented reality (hereinafter, referred to as “AR”) screen or a virtual reality (hereinafter, referred to as “VR”) screen to a user.

In the case of wearable devices such as the HMD device or the AR glasses, a display specification of approximately 3000 pixels per inch (PPI) or higher is required to allow users to use them for a long time without symptoms of dizziness. To this end, organic light-emitting diode on silicon (“OLEDoS”) technology used in high-resolution small-sized organic light-emitting display devices is emerging. The OLEDoS is a technology in which organic light-emitting diodes (“OLEDs”) are disposed on a semiconductor wafer substrate on which complementary metal oxide semiconductor (“CMOS”) elements are disposed.

In order to manufacture a display panel with a high resolution of about 3000 PPI or higher, a high-resolution deposition mask is required. For example, the deposition mask may be manufactured by forming a membrane having a plurality of pixel openings on a substrate and partially etching the substrate to form cell openings that expose the pixel openings. However, after manufacturing the deposition mask, warpage or deformation may occur due to residual stress inside the membrane, difference in thermal expansion rate between the substrate and the membrane, and the like. In this case, in a deposition process of forming organic light-emitting layers on a backplane substrate, a deposition mask may not be brought into sufficiently close contact with the backplane substrate, so that misalignment may occur between the organic light-emitting layers and anode electrodes on the backplane substrate.

### SUMMARY

Aspects and features of embodiments of the present disclosure provide a deposition mask that is improved to be sufficiently brought into close contact with a substrate in a deposition process, a deposition apparatus including the same, and an electronic device manufactured by using the same.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a deposition mask includes a mask frame defining cell openings therein, and a membrane including mask cell regions disposed above and overlapping the cell openings, respectively, and a grid region disposed between the mask cell regions. A first recess is defined at a surface portion of the membrane, and the mask frame includes a rib region defining the cell openings and a first lower electrode disposed to be spaced apart from the first recess in a thickness direction of the mask frame.

The first recess may be defined at a top surface portion of the grid region of the membrane, and the first lower electrode may be disposed on a bottom surface of the rib region of the mask frame.

The first lower electrode may be disposed in a top surface portion of the rib region of the mask frame.

The membrane may define a first opening penetrating the grid region to partially expose the rib region of the mask frame, and may further include a dielectric pattern disposed in the first opening.

The first recess may be defined in a top surface portion of the dielectric pattern.

The first lower electrode may be disposed on a bottom surface of the rib region of the mask frame.

The first lower electrode may be disposed in a top surface portion of the rib region of the mask frame, and the dielectric pattern may be disposed on the first lower electrode.

The first recess may be defined at a top surface portion of the grid region of the membrane, and a second recess different from the first recess may be defined at a top surface portion of an edge region of the membrane.

The mask frame may further include a second lower electrode different from the first lower electrode and disposed to be spaced apart from the second recess in the thickness direction of the mask frame.

According to one or more embodiments of the present disclosure, a deposition apparatus includes a deposition source, a deposition mask disposed above the deposition source, and an electrostatic chuck configured to support a substrate such that the substrate is disposed on the deposition mask. A first upper electrode is disposed on the substrate. The deposition mask includes a mask frame defining cell openings therein, and a membrane including mask cell regions disposed above and overlapping the cell openings, respectively, and a grid region disposed between the mask cell regions. The mask frame includes a rib region defining the cell openings and a first lower electrode disposed to be spaced apart from the first upper electrode in a thickness direction of the mask frame.

A first recess may be defined at a top surface portion of the grid region of the membrane, and the first upper electrode may be configured to be disposed in the first recess.

The first upper electrode may have a thickness equal to or greater than a depth of the first recess so as to be in contact with a bottom surface of the first recess.

The first lower electrode may be disposed on a bottom surface of the rib region of the mask frame or in a top surface portion of the rib region of the mask frame.

The membrane may define a first opening penetrating the grid region to partially expose the rib region of the mask frame, and may further include a dielectric pattern disposed in the first opening.

A first recess may be defined in a top surface portion of the dielectric pattern, and the first upper electrode may be configured to be disposed in the first recess.

The first lower electrode may be disposed in a top surface portion of the rib region of the mask frame, and the dielectric pattern may be disposed on the first lower electrode.

The substrate may include display cell regions disposed on the mask cell regions, respectively, and a scribe lane region disposed between the display cell regions, and the first upper electrode may be disposed on the scribe lane region.

Anode electrodes may be disposed on the display cell regions, and the first upper electrode may be made of the same material as the anode electrodes.

A second upper electrode different from the first upper electrode may be disposed on an edge region of the substrate, and the mask frame may further include a second lower electrode different from the first lower electrode and disposed to be spaced apart from the second upper electrode in the thickness direction of the mask frame.

A second recess different from the first recess may be defined at a top surface portion of an edge region of the membrane, and the second upper electrode may be configured to be disposed in the second recess.

According to one or more embodiments of the present disclosure, an electronic device may include a display panel. The display panel may include a substrate and a plurality of light-emitting layers formed on the substrate by using a deposition mask. The deposition mask may include a mask frame defining cell openings therein, and a membrane comprising mask cell regions disposed above and overlapping the cell openings, respectively, and a grid region disposed between the mask cell regions. A first recess may be defined at a surface portion of the membrane, and the mask frame may include a rib region defining the cell openings and a first lower electrode disposed to be spaced apart from the first recess in a thickness direction of the mask frame.

In accordance with the above embodiments, the electrostatic force provided from the electrostatic chuck may be increased by the upper electrode provided on the substrate and the lower electrode provided on the mask frame, and accordingly, the deposition mask may be brought into sufficiently close contact with the substrate.

Other features and embodiments may be apparent from the following detailed description and the drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view illustrating a display device;

FIG. 2 is a block diagram for explaining the display device shown in FIG. 1;

FIG. 3 is an equivalent circuit diagram for explaining an example of a first sub-pixel shown in FIG. 2;

FIG. 4 is a schematic plan view illustrating an example of the display panel shown in FIG. 1;

FIG. 5 is a schematic plan view illustrating an example of the display area shown in FIG. 4;

FIG. 6 is a schematic plan view illustrating another example of the display area shown in FIG. 4;

FIG. 7 is a cross-sectional view illustrating an example of the display panel taken along line I-I′ of FIG. 5;

FIG. 8 is a schematic perspective view illustrating an example of a head mounted display;

FIG. 9 is a schematic exploded perspective view illustrating the head mounted display shown in FIG. 8;

FIG. 10 is a schematic perspective view illustrating another example of a head mounted display;

FIG. 11 is a schematic view illustrating a deposition mask and a deposition apparatus including the deposition mask according to one embodiment of the present disclosure;

FIG. 12 is a schematic plan view illustrating a substrate shown in FIG. 11;

FIG. 13 is a schematic plan view illustrating the deposition mask shown in FIG. 11;

FIG. 14 is a schematic enlarged plan view illustrating mask cell regions shown in FIG. 13;

FIG. 15 is a schematic cross-sectional view taken along line II-II′ shown in FIG. 13;

FIG. 16 is a schematic cross-sectional view illustrating a state in which the substrate shown in FIG. 15 is disposed on the deposition mask;

FIG. 17 is a cross-sectional view illustrating a deposition mask according to another embodiment of the present disclosure;

FIG. 18 is a schematic cross-sectional view illustrating a deposition mask according to still another embodiment of the present disclosure;

FIG. 19 is a schematic cross-sectional view illustrating a deposition mask according to still another embodiment of the present disclosure;

FIG. 20 is a schematic plan view illustrating another example of the substrate shown in FIG. 11;

FIG. 21 is a schematic plan view illustrating a deposition mask according to still another embodiment of the present disclosure;

FIG. 22 is a schematic cross-sectional view taken along line III-III′ shown in FIG. 21;

FIG. 23 is a schematic cross-sectional view illustrating a deposition mask according to still another embodiment of the present disclosure;

FIG. 24 is a schematic cross-sectional view illustrating a deposition mask according to still another embodiment of the present disclosure; and

FIG. 25 is a schematic cross-sectional view illustrating a deposition mask according to still another embodiment of the present disclosure.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used

herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

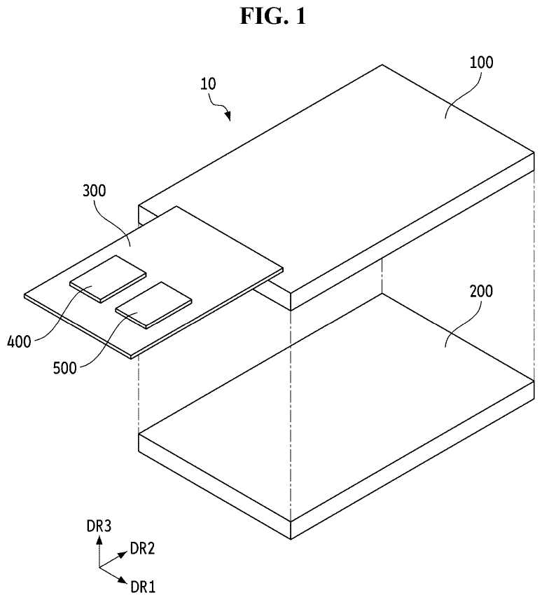

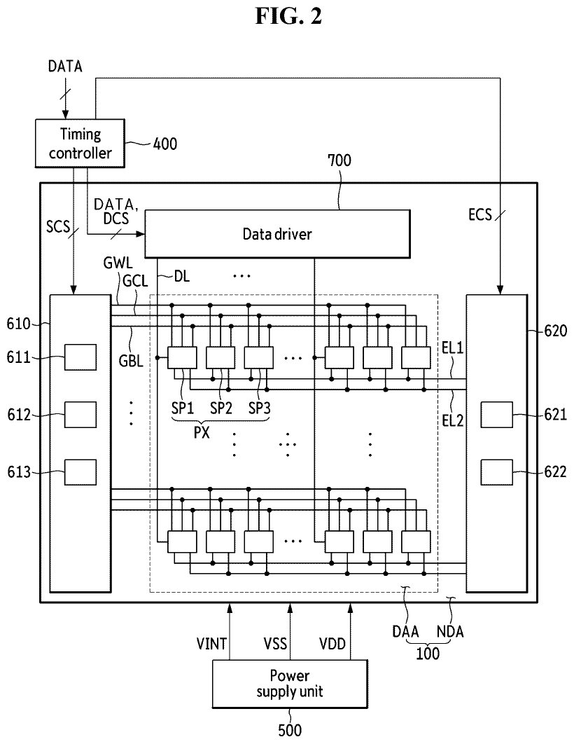

FIG. 1 is an exploded perspective view illustrating a display device. FIG. 2 is a block diagram for explaining the display device shown in FIG. 1.

Referring to FIGS. 1 and 2, a display device 10 may be a device displaying a moving image or a still image. The display device 10 may be applied to portable electronic devices such as a mobile phone, a smartphone, a tablet personal computer (“PC”), a mobile communication terminal, an electronic organizer, an electronic book, a portable multimedia player (“PMP”), a navigation system, an ultra-mobile PC (“UMPC”), and the like. For example, the display device 10 may be applied as a display unit of electronic devices such as a television, a laptop, a monitor, a billboard, an Internet-of-Things (“IoT”) device, and the like. Alternatively, the display device 10 may be applied to electronic devices such as a smart watch, a watch phone, a head mounted display (“HMD”) for implementing virtual reality and augmented reality, and the like.

The display device 10 may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. As shown in FIG. 2, the display panel 100 may be divided into a display area DAA displaying an image and a non-display area NDA not displaying an image.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

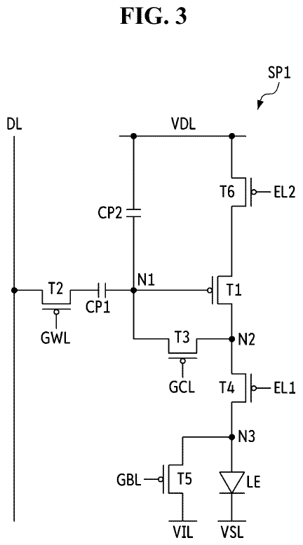

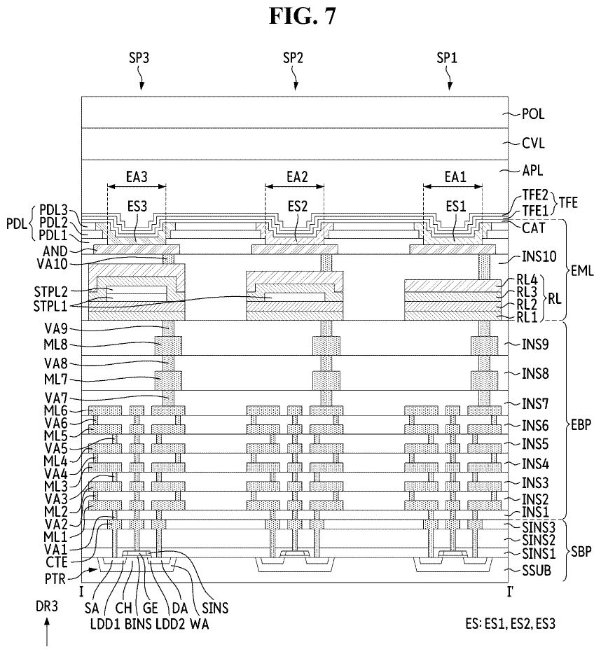

The plurality of pixels PX may include a plurality of sub-pixels SP1, SP2, and SP3. The plurality of sub-pixels SP1, SP2, and SP3 may include a plurality of pixel transistors (see FIG. 3). The plurality of pixel transistors may be formed by a semiconductor process, and may be disposed on a semiconductor substrate SSUB (see FIG. 7). For example, the plurality of pixel transistors of the data driver 700 may be formed through a complementary metal oxide semiconductor (CMOS) process, but the present disclosure is not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. The plurality of scan transistors and the plurality of light-emitting transistors may be disposed on the semiconductor substrate SSUB (see FIG. 7) through a semiconductor process. For example, the plurality of scan transistors and the plurality of light-emitting transistors may be formed through a CMOS process, but the embodiment of the present specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and disposed on the semiconductor substrate SSUB (see FIG. 7). For example, the plurality of data transistors may be formed through a CMOS process, but the present disclosure is not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

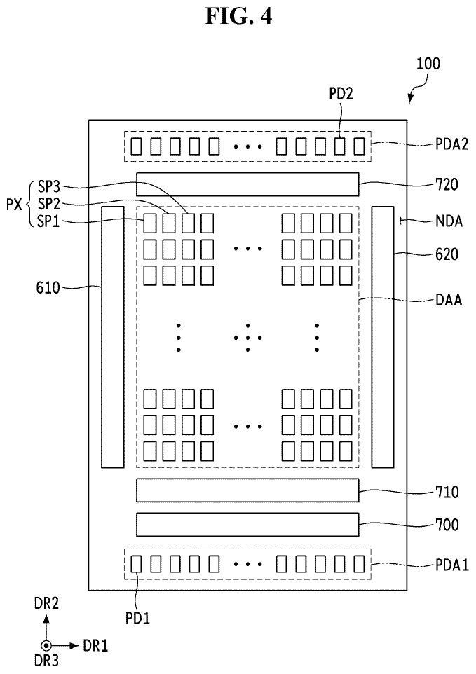

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

As another example, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and disposed on the semiconductor substrate SSUB (see FIG. 7). For example, the plurality of timing transistors and the plurality of power transistors may be formed through a CMOS process, but the present disclosure is not limited thereto. Each of the timing control circuit 400 and the power supply circuit 500 may be disposed between the data driver 700 and the first pad portion PDA1 (see FIG. 4).

FIG. 3 is an equivalent circuit diagram for explaining an example of a first sub-pixel shown in FIG. 2.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the present disclosure is not limited thereto.

For another example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (“MOSFET”). For example, each of the first to sixth transistors T1 to T6 may be a P-type MOSFET, but the present disclosure is not limited thereto. Each of the first to sixth transistors T1 to T6 may be an N-type MOSFET in another embodiment. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For another example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the present disclosure.

FIG. 4 is a schematic plan view illustrating an example of the display panel shown in FIG. 1.

Referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, as shown in FIG. 4, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA in another embodiment.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, as shown in FIG. 4, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally.

The plurality of second pads PD2 may be connected to a jig or probe pins during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, as shown in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, as shown in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, as shown in FIG. 4, the second distribution circuit 720 may be disposed on the upper side of the display area DAA.

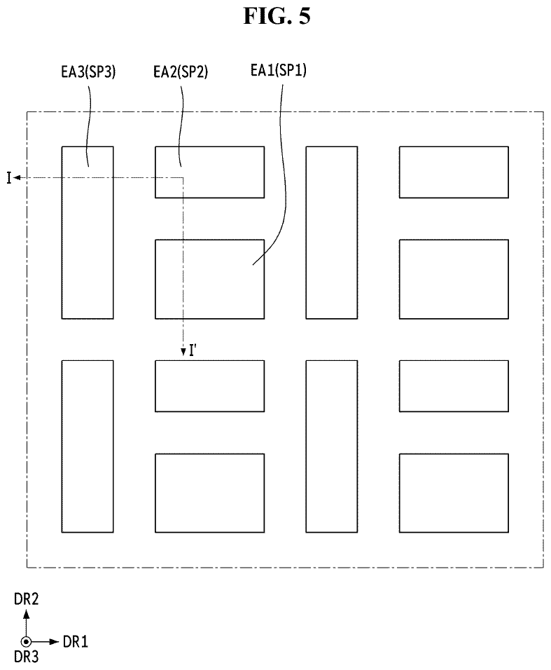

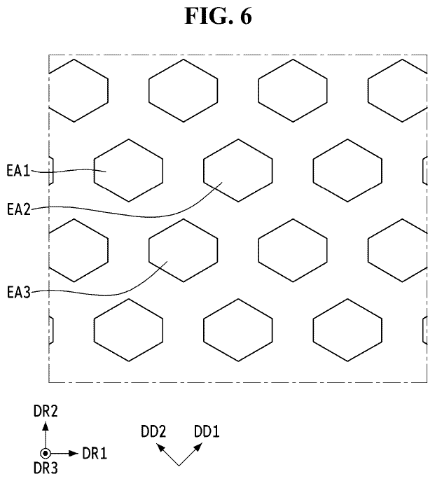

FIG. 5 is a schematic plan view illustrating an example of the display area shown in FIG. 4. FIG. 6 is a schematic plan view illustrating another example of the display area shown in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 7). For example, each of the first emission area EA1, the second emission area EA2, and the third emission area EA3 may be an area defined by a first pixel defining film PDL1 (see FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nanometers (nm) to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

As another example, as shown in FIG. 6, the first emission area EA1, the second emission area EA2, and the third emission area EA3 may be disposed in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 5 and 6 that each of the plurality of pixels PX includes the three emission areas EA1, EA2, and EA3, the present disclosure is not limited thereto. That is, each of the plurality of pixels PX may include four emission areas. Further, each of the emission areas EA1, EA2, and EA3 may have a polygonal, circular, elliptical, or atypical shape in a plan view, unlike those shown in FIGS. 5 and 6.

The arrangement of the emission areas EA1, EA2, and EA3 of the plurality of pixels PX is not limited to that illustrated in FIGS. 5 and 6. For another example, the emission areas of the plurality of pixels PX may be disposed in a stripe structure in which the emission areas are arranged in the first direction DR1, a PenTile® structure in which the emission areas are arranged in a diamond shape, or the like.

FIG. 7 is a cross-sectional view illustrating an example of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than an impurity concentration of the source region SA. The second low-concentration impurity region LDD2 may be a region having an impurity concentration lower than an impurity concentration of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor

substrate SSUB. The first semiconductor insulating film SINS1 may be formed of silicon carbonitride (SiCN) or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the embodiment of the present specification is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through contact plugs penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the embodiment of the present specification is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors C1 and C2 may be implemented by the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE (see FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may be made of substantially the same material. The first to eighth conductive layers ML1 to ML8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. The first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOx)-based inorganic film, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 angstroms (Å). The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the embodiment of the present specification is not limited thereto.

Each of the ninth vias VA9 may penetrate the ninth insulating film INS9 and be connected to the eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RLA, a first step layer STPL1, and a second step layer STPL2. For example, the reflective electrode layer RL may include first to fourth reflective electrodes RL1, RL2, RL3, and RLA as shown in FIG. 7.

Each of the first reflective electrodes RL1 may be disposed on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. In addition, the second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RLA to advantageously reflect the light of the third color emitted from the light-emitting stack ES.

The first step layer STPL1 and the second step layer STPL2 may be formed of silicon carbonitride (SiCN) or a silicon oxide (SiOx)-based inorganic film, but the embodiment of the present specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to advantageously reflect the light. In addition, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOx)-based inorganic film, but the present disclosure is not limited thereto.

Each of the tenth vias VA10 may penetrate the tenth insulating film VA10 and be connected to the reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TIN).

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may define openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the embodiment of the present specification is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not shown in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

The first to third light-emitting layers EML1, EML2, and EML3 may be disposed in the openings of the pixel defining film PDL, respectively, on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

The electron transporting layer ETL may be disposed on the first to third light-emitting layers EML1, EML2, and EML3 and the hole transporting layer HTL, and the electron injecting layer EIL may be disposed on the electron transporting layer ETL.

For another example, although not shown, a plurality of trenches (not shown) may be disposed between the first to third emission areas EA1, EA2, and EA3. The trenches may have a ring shape surrounding the first to third emission areas EA1, EA2, and EA3, respectively, and may be formed to penetrate the pixel defining film PDL. The hole injecting layer HIL and the hole transporting layer HTL disposed on the first electrodes AND of the first to third emission areas EA1, EA2, and EA3 may be disconnected from each other by the trenches.

For another example, the first to third light-emitting stacks ES1, ES2, and ES3 may be disposed in the openings of the pixel defining film PDL, respectively, and may not be disposed on the pixel defining film PDL. In this case, the first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may be formed of a transparent conductive material (“TCO”) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (“CVD”) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but the embodiment of the present specification is not limited thereto. The second encapsulation inorganic film TFE2 may be formed by an atomic layer deposition (“ALD”) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as acrylic resin, epoxy resin, phenolic resin, polyamide resin, or polyimide resin.

The cover layer CVL may be disposed on the adhesive layer APL. The cover layer CVL may be a glass substrate or a polymer resin. When the cover layer CVL is a glass substrate, it may be attached onto the adhesive layer APL, and may serve as an encapsulation substrate. When the cover layer CVL is a polymer resin, it may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a N4 plate (quarter-wave plate), but the present disclosure is not limited thereto.

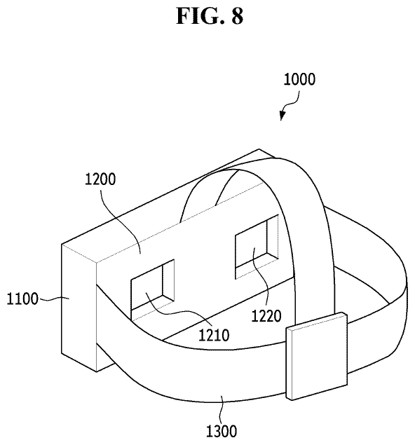

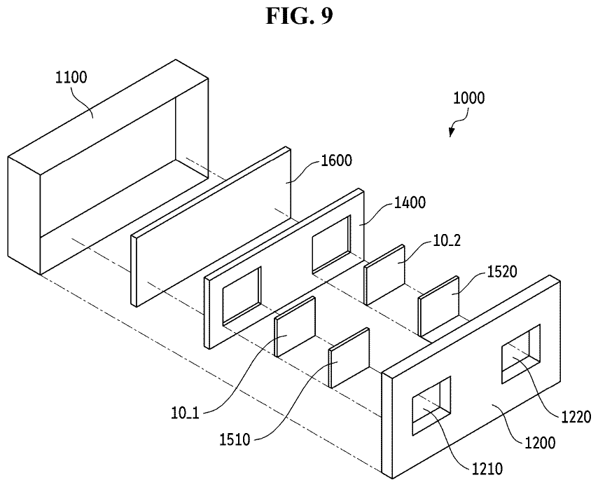

FIG. 8 is a schematic perspective view illustrating a head mounted display. FIG. 9 is a schematic exploded perspective view illustrating an example of the head mounted display shown in FIG. 8.

Referring to FIGS. 8 and 9, a head mounted display 1000 according to one embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

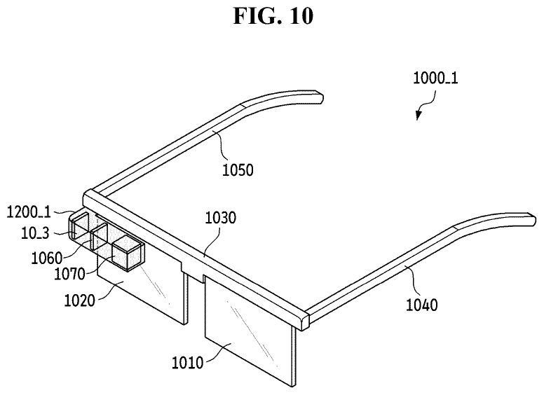

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head mounted display 1000 may be provided in the form of glasses as shown in FIG. 10.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another example of a head mounted display.

Referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path thereof is changed by the optical path conversion member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the present disclosure is not limited thereto. For another example, the display device housing 1200_1 may be disposed at the left end of the support frame 1030, and in this case, the image of the display device 10_3 may be provided to the user's left eye. As another example, the display device housing 1200_1 may be disposed at both the left and right ends of the support frame 1030, and in this case, the user may view the image displayed on the display device 10_3 through both the left and right eyes.

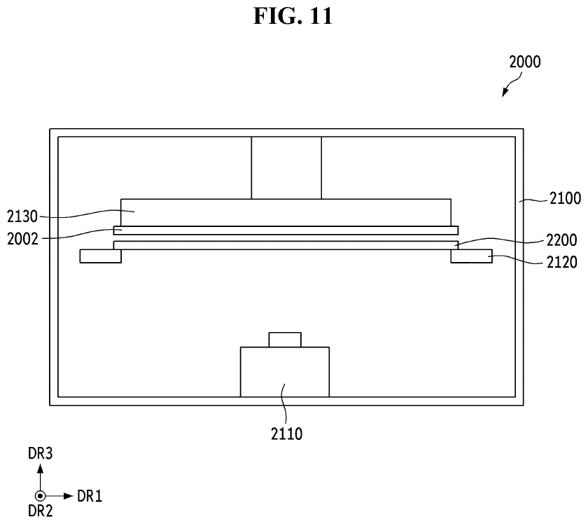

FIG. 11 is a schematic view illustrating a deposition mask and a deposition apparatus including the deposition mask according to one embodiment of the present disclosure.

Referring to FIG. 11, a deposition apparatus 2000 and a deposition mask 2200 according to one embodiment of the present disclosure may be used to form an inorganic or organic material layer on a substrate 2002. According to one embodiment of the present disclosure, a deposition apparatus 2000 and a deposition mask 2200 may be used to form light-emitting layers of the light-emitting stack ES on the substrate 2002 in a manufacturing process of the display panel 100 (see FIG. 1). For example, as illustrated in FIG. 7, the semiconductor backplane SBP and the light emitting element backplane EBP may be disposed on the substrate 2002, and the reflective electrodes RL and the insulating film INS10 may be disposed on the light emitting element backplane EBP. Electrode patterns, for example, the first electrodes AND may be disposed on the insulating film INS10, and the first electrodes AND may be electrically connected to the reflective electrodes RL through the vias VA10. For example, the deposition apparatus 2000 and the deposition mask 2200 may be used to form light-emitting layers on the electrode patterns. As an example, the deposition apparatus 2000 and the deposition mask 2200 may be used to form first light-emitting layers for emitting first light having a red wavelength band on the first electrodes AND of the first emission areas EA1. As another example, the deposition apparatus 2000 and the deposition mask 2200 may be used to form second light-emitting layers for emitting second light having a green wavelength band on the first electrodes AND of the second emission areas EA2. As still another example, the deposition apparatus 2000 and the deposition mask 2200 may be used to form third light-emitting layers for emitting third light having a blue wavelength band on the first electrodes AND of the third emission areas EA3.

The deposition apparatus 2000 according to one embodiment of the present disclosure may include a process chamber 2100, a deposition source 2110 disposed in the process chamber 2100, a deposition mask 2200 disposed above the deposition source 2110, a support member 2120 for supporting the deposition mask 2200, an electrostatic chuck 2130 disposed above the deposition mask 2200 to support the substrate 2002, and the like.

The process chamber 2100 may have an internal space, and a deposition process for forming a material layer on the substrate 2002 may be performed in the internal space of the process chamber 2100. The process chamber 2100 may be connected to a vacuum pump (not shown), and a vacuum atmosphere may be created in the internal space of the process chamber 2100 by the vacuum pump.

The deposition source 2110 may be disposed in the process chamber 2100, and a deposition material may be stored in the deposition source 2110. The deposition source 2110 may evaporate the deposition material, such as an organic material, an inorganic material, or a conductive material, toward the substrate 2002, and the evaporated deposition material may be deposited on the substrate 2002 through the deposition mask 2200. For example, the deposition source 2110 may evaporate an organic material for forming light-emitting layers on the substrate 2002, and may have a heater (not shown) for evaporating the organic material.

The support member 2120 for supporting the deposition mask 2200 may be disposed above the deposition source 2110. For example, the support member 2120 may support the edge portion of the deposition mask 2200, and the deposition mask 2200 may have pixel openings and cell openings for providing the organic material evaporated from the deposition source onto the substrate 2002. Although not shown, the support member 2120 may be configured to be rotatable and movable in vertical and horizontal directions by a driving unit (not shown) in order to adjust the position and angle of the deposition mask 2200.

The electrostatic chuck 2130 for supporting the substrate 2002 may be disposed above the deposition mask 2200. The electrostatic chuck 2130 may hold the substrate 2002 using an electrostatic force such that the substrate 2002 faces downward, that is, the substrate 2002 faces the deposition mask 2200. In this case, the substrate 2002 may be disposed with a front surface facing downward, and the electrostatic chuck 2130 may hold a back surface of the substrate 2002 using an electrostatic force.

Although not shown, the electrostatic chuck 2130 may be configured to be rotatable and movable in the vertical and horizontal directions by a driving unit (not shown) in order to adjust the position and angle of the substrate 2002. Further, after the deposition mask 2200 is disposed on the support member 2120 and the substrate 2002 is held onto a bottom surface of the electrostatic chuck 2130, the positional alignment between the substrate 2002 and the deposition mask 2200 may be performed. After the positional alignment between the substrate 2002 and the deposition mask 2200 is performed, the electrostatic chuck 2130 may move downward or the support member 2120 may move upward, so that the deposition mask 2200 may be brought into close contact with the front surface of the substrate 2002.

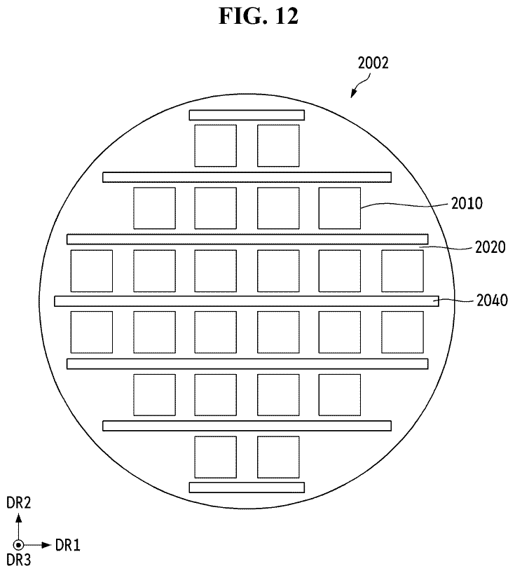

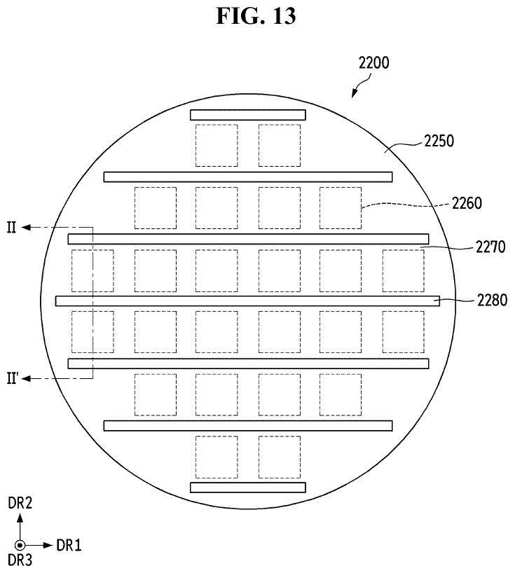

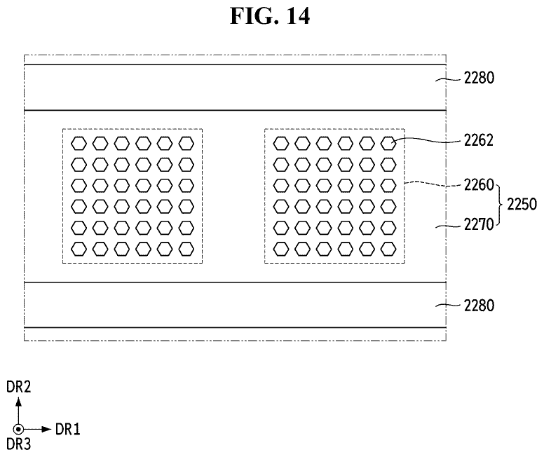

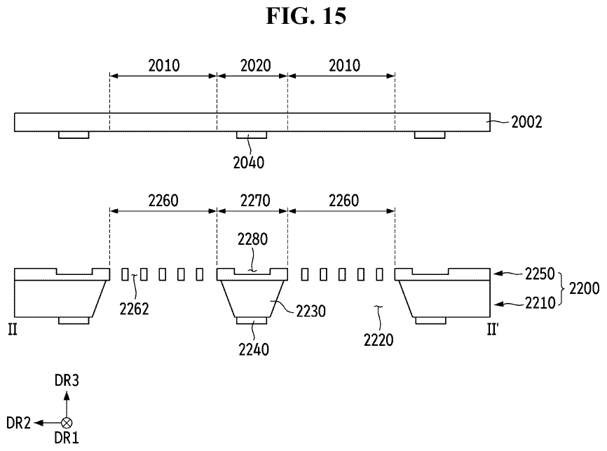

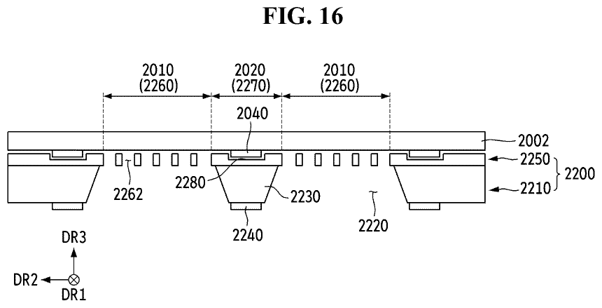

FIG. 12 is a schematic plan view illustrating the substrate shown in FIG. 11. FIG. 13 is a schematic plan view illustrating the deposition mask shown in FIG. 11. FIG. 14 is a schematic enlarged plan view illustrating mask cell regions shown in FIG. 13. FIG. 15 is a schematic cross-sectional view taken along line II-II′ shown in FIG. 13. FIG. 16 is a schematic cross-sectional view illustrating a state in which the substrate shown in FIG. 15 is disposed on the deposition mask. The “plan view” is a view in a thickness direction (i.e., third direction DR3) of the mask frame 2210.

Referring to FIGS. 12 to 16, the deposition mask 2200 according to one embodiment of the present disclosure may be used as a shadow mask in a deposition process for forming light-emitting layers on the substrate 2002.

The substrate 2002 may include a plurality of display cell regions 2010 and a scribe lane region 2020 disposed between the display cell regions 2010. As shown in FIG. 12, the display cell regions 2010 may be arranged in a matrix form along a first direction DR1 and a second direction DR2 intersecting the first direction DR1. For example, the first direction DR1 may be a first horizontal direction, and the second direction DR2 may be a second horizontal direction perpendicular to the first direction DR1. However, the number and arrangement directions of the display cell regions 2010 may be variously changed, so that the scope of the present disclosure is not limited thereby.

Each of the display cell regions 2010 may include a semiconductor backplane SBP (see FIG. 7), a light-emitting element backplane EBP (see FIG. 7) disposed on the semiconductor backplane SBP, a reflective electrode layer RL (see FIG. 7) disposed on the light-emitting element backplane EBP, and an insulating film INS10 (see FIG. 7) disposed on the reflective electrode layer RL. In particular, each of the display cell regions 2010 may include anode electrodes AND (see FIG. 7) disposed on the insulating film INS10. That is, the plurality of anode electrodes AND may be disposed on the front surface of the substrate 2002.

The deposition mask 2200 may include a mask frame 2210 and a membrane 2250 disposed on the mask frame 2210. The mask frame 2210 may define a plurality of cell openings 2220 therein, and may include a rib region 2230 defining the cell openings 2220. The membrane 2250 may include a plurality of mask cell regions 2260 disposed above the cell openings 2220, respectively, and a grid region 2270 disposed on the rib region 2230.

As shown in FIG. 13, the mask cell regions 2260 may be arranged in a matrix form along the first direction DR1 and the second direction DR2 intersecting the first direction DR1. For example, the first direction DR1 may be a first horizontal direction, and the second direction DR2 may be a second horizontal direction perpendicular to the first direction DR1. The mask cell regions 2260 may be arranged to correspond to the display cell regions 2010 of the substrate 2002. However, the number and arrangement directions of the mask cell regions 2260 may be variously changed, so that the scope of the present disclosure is not limited thereby.

The mask frame 2210 may define a plurality of cell openings 2220 corresponding to the mask cell regions 2260, respectively. For example, the cell openings 2220 may be formed to penetrate the mask frame 2210 by a dry or wet etching process, so that the mask cell regions 2260 of the membrane 2250 may be exposed by the cell openings 2220 of the mask frame 2210, respectively.

The mask frame 2210 may include a semiconductor substrate. For example, the membrane 2250 may be disposed on a silicon substrate and, in this case, the silicon substrate may function as the mask frame 2210. Although not shown, the mask frame 2210 may include an inorganic film (not shown) disposed on the silicon substrate and, in this case, the cell openings 2220 may be defined to expose the mask cell regions 2260 while penetrating the silicon substrate and the inorganic film. For example, a silicon oxide film formed by a thermal oxidation process or a chemical vapor deposition process may be used as the inorganic film.

The membrane 2250 may be made of a material different from a material of the inorganic film. For example, a silicon nitride film formed by a chemical vapor deposition process may be used as the membrane 2250. In this case, the inorganic film may function as an adhesive film between the silicon substrate and the membrane 2250. However, the membrane 2250 may be made of a material different from the above material, so that the scope of the present disclosure is not limited by the silicon nitride film.

Further, each of the mask cell regions 2260 of the membrane 2250 may define a plurality of pixel openings 2262 therein. The pixel openings 2262 may function as paths for providing an organic material in a deposition process for forming the organic light-emitting layers of the light-emitting stack ES. That is, the pixel openings 2262 may be arranged to correspond to the anode electrodes AND of each of the display cell regions 2010. For example, as shown in FIG. 14, the pixel openings 2262 may be arranged in a matrix form along the first direction DR1 and the second direction DR2, and may be formed to penetrate the mask cell regions 2260 of the membrane 2250 by an anisotropic etching process after the membrane 2250 is disposed on the inorganic film. In this case, the inorganic film may function as an etch stop film during the anisotropic etching process. The cell openings 2220 of the mask frame 2210 may be formed to expose the mask cell regions 2260 by an etching process after the pixel openings 2262 are formed, so that the pixel openings 2262 may communicate with the cell openings 2220.

In accordance with one embodiment of the present disclosure, a recess 2280 may be defined at a surface portion of the membrane 2250. For example, a plurality of recesses 2280 may be defined at top surface portions of the grid region 2270 of the membrane 2250. That is, the plurality of recesses 2280 may be defined between the mask cell regions 2260 of the membrane 2250, and may extend in the first direction DR1 as shown in FIG. 13. However, the number and extension direction of the recesses 2280 may be variously changed, so that the scope of the present disclosure is not limited thereby.

The mask frame 2210 may include lower electrodes 2240 arranged to be spaced apart from the recesses 2280 in a thickness direction of the mask frame 2210. Specifically, the lower electrodes 2240 may correspond to the recesses 2280, respectively, and may be arranged to overlap the rib region 2230 of the mask frame 2210 in a third direction DR3 perpendicular to the first and second directions DR1 and DR2. For example, as shown in FIG. 15, the lower electrodes 2240 may be disposed on a bottom surface of the rib region 2230 of the mask frame 2210, and may each extend in the first direction DR1.

The lower electrodes 2240 of the mask frame 2210 may include a metal material. For example, the lower electrodes 2240 of the mask frame 2210 may include any one of copper (Cu), aluminum (Al), tungsten (W), molybdenum (Mo), chromium (Cr), gold (Au), titanium (Ti), nickel (Ni), and neodymium (Nd), or an alloy of any one of them, and may be formed by a physical vapor deposition process, a chemical vapor deposition process, an atomic layer deposition process, or the like. Specifically, after a metal layer made of the metal material may be disposed on the bottom surface of the mask frame 2210, the metal layer may be patterned to form the lower electrodes 2240 on the bottom surface of the mask frame 2210.

Further, upper electrodes 2040 corresponding to the lower electrodes 2240 of the mask frame 2210 may be disposed on the front surface of the substrate 2002. Specifically, the upper electrodes 2040 may be disposed between the display cell regions 2010, that is, on the scribe lane region 2020, and may each extend in the first direction DR1 as shown in FIG. 12. That is, as shown in FIG. 15, the upper electrodes 2040 disposed on the substrate 2002 and the lower electrodes 2240 of the mask frame 2210 may correspond to each other in the vertical direction, that is, in the third direction DR3.

The upper electrodes 2040 of the substrate 2002 may include a metal material. For example, the upper electrodes 2040 of the substrate 2002 may include any one of copper (Cu), aluminum (Al), tungsten (W), molybdenum (Mo), chromium (Cr), gold (Au), titanium (Ti), nickel (Ni), and neodymium (Nd), or an alloy of any one of them, and may be formed by a physical vapor deposition process, a chemical vapor deposition process, an atomic layer deposition process, or the like. For example, the upper electrodes 2040 of the substrate 2002 may be formed of the same material as the anode electrodes AND, and may be formed simultaneously with the anode electrodes AND. Specifically, after the metal layer made of the metal material is disposed on the front surface of the substrate 2002, the metal layer may be patterned to simultaneously form the anode electrodes AND and the upper electrodes 2040 on the front surface of the substrate 2002.

Although not shown, electrostatic electrodes (not shown) may be disposed in the electrostatic chuck 2130 for holding the substrate 2002, and the back surface of the substrate 2002 may be attached onto the bottom surface of the electrostatic chuck 2130 by the electrostatic force provided from the electrostatic chuck 2130. Further, the deposition mask 2200 may be attached onto the front surface of the substrate 2002 by the electrostatic force. In this case, the upper electrodes 2040 of the substrate 2002 and the lower electrodes 2240 of the deposition mask 2200 may correspond to each other in the third direction DR3, so that the electrostatic force may increase between the upper electrodes 2040 and the lower electrodes 2240. As a result, the deposition mask 2200 may be brought into sufficiently close contact with the front surface of the substrate 2002.

In accordance with one embodiment of the present disclosure, in order to reduce a gap between the substrate 2002 and the deposition mask 2200, the deposition mask 2200 may define recesses 2280 into which the upper electrodes 2040 of the substrate 2002 are inserted. For example, the recesses 2280 that are defined to allow the upper electrodes 2040 of the substrate 2002 to be inserted thereinto may be provided at top surface portions of the membrane 2250. Specifically, the recesses 2280 may be defined at top surface portions of the grid region 2270 of the membrane 2250, and the upper electrodes 2040 may be inserted into the recesses 2280. That is, the upper electrodes 2040 of the substrate 2002, the recesses 2280 of the deposition mask 2200, and the lower electrodes 2240 may be arranged in the vertical direction, that is, the third direction DR3, and a distance between the upper electrodes 2040 and the lower electrodes 2240 may be reduced by the recesses 2280.

In particular, the electrostatic force provided between the substrate 2002 and the deposition mask 2200 may be in inverse proportional to the square of the distance between the upper electrodes 2040 and the lower electrodes 2240, so that the electrostatic force between the substrate 2002 and the deposition mask 2200 may be increased by the recesses 2280. In this case, it is preferable that the upper electrodes 2040 are brought into close contact with the bottom surfaces of the recesses 2280 so as to reduce the gap between the substrate 2002 and the deposition mask 2200. In accordance with one embodiment of the present disclosure, the upper electrodes 2040 of the substrate 2002 may have a thickness that is greater than or equal to a depth of the recesses 2280 in the third direction DR3 to be in contact with the bottom surfaces of the recesses 2280. However, when the thickness of the upper electrodes 2040 is excessively greater than the depth of the recesses 2280, the gap between the display cell regions 2010 of the substrate 2002 and the mask cell regions 2260 of the deposition mask 2200 may be increased, so that it is preferable that the thickness of the upper electrodes 2040 is less than or equal to about 1.5 times the depth of the recesses 2280. That is, the thickness of the upper electrodes 2040 may be greater than or equal to the depth of the recesses 2280, and less than or equal to about 1.5 times the depth of the recesses 2280.

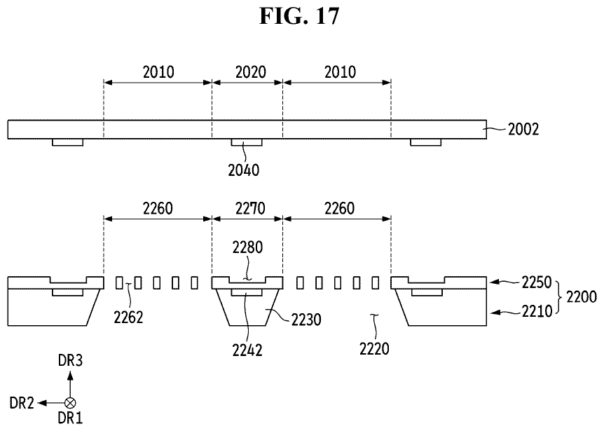

FIG. 17 is a cross-sectional view illustrating a deposition mask according to another embodiment of the present disclosure.

Referring to FIG. 17, the deposition mask 2200 according to another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above the cell openings 2220, respectively, and the grid region 2270 disposed between the mask cell regions 2260. The recesses 2280 may be defined at the surface portions of the membrane 2250, and the mask frame 2210 may include lower electrodes 2242 arranged to be spaced apart from the recesses 2280 in the thickness direction of the mask frame 2210.

The upper electrodes 2040 may be disposed on the front surface of the substrate 2002 to correspond to the lower electrodes 2242 of the mask frame 2210 in the third direction DR3, and the substrate 2002 may be disposed on the deposition mask 2200 such that the upper electrodes 2040 may be inserted into the recesses 2280 of the membrane 2250. In the present embodiment, the other elements except the lower electrodes 2242 are substantially the same as those already described with reference to FIGS. 12 to 16, so that the description thereof is omitted.

In accordance with the present embodiment, the lower electrodes 2242 may be disposed in top surface portions of the rib region 2230 of the mask frame 2210. In particular, the lower electrodes 2242 may be disposed to overlap the recesses 2280 of the membrane 2250 in the third direction DR3. In this case, in the deposition process, only the grid region 2270 of the membrane 2250 may be disposed between the lower electrodes 2242 of the mask frame 2210 and the upper electrodes 2040 of the substrate 2002, so that the gap between the lower electrodes 2242 and the upper electrodes 2040 can be considerably reduced. As a result, the electrostatic force between the lower electrodes 2242 of the mask frame 2210 and the upper electrodes 2040 of the substrate 2002 may be considerably increased, so that the deposition mask 2200 may be brought into sufficiently close contact with the front surface of the substrate 2002.

The lower electrodes 2242 of the mask frame 2210 may include a metal material. For example, the lower electrodes 2242 of the mask frame 2210 may include any one of copper (Cu), aluminum (Al), tungsten (W), molybdenum (Mo), chromium (Cr), gold (Au), titanium (Ti), nickel (Ni), and neodymium (Nd), or an alloy of any one of them, and may be formed by a physical vapor deposition process, a chemical vapor deposition process, an atomic layer deposition process, or the like. For example, the lower electrodes 2242 of the mask frame 2210 may be formed by a damascene process.

For another example, when the mask frame 2210 includes a silicon substrate (not shown) and an inorganic film (not shown) disposed on the silicon substrate, the lower electrodes 2242 may be disposed in the inorganic film on the silicon substrate by the damascene process. In this case, the lower electrodes 2242 and the inorganic film may have the same thickness, and the membrane 2250 may be disposed on the lower electrodes 2242 and the inorganic film.

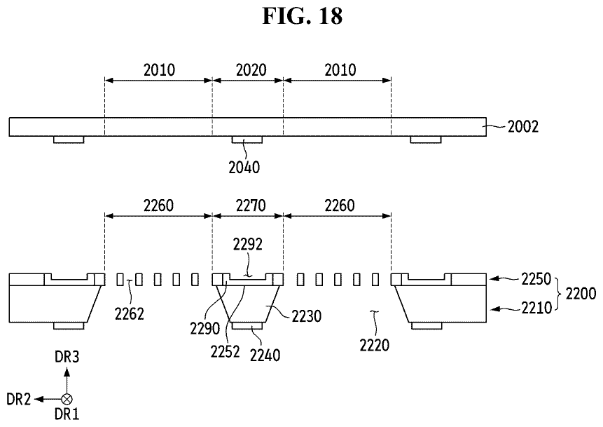

FIG. 18 is a schematic cross-sectional view illustrating a deposition mask according to still another embodiment of the present disclosure.

Referring to FIG. 18, the deposition mask 2200 according to still another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above the cell openings 2220, respectively, and the grid region 2270 disposed between the mask cell regions 2260. Recesses 2292 may be defined at surface portions of the membrane 2250, and the mask frame 2210 may include the lower electrodes 2240 arranged to be spaced apart from the recesses 2292 in the thickness direction of the mask frame 2210. For example, the lower electrodes 2240 may be disposed on the bottom surface of the rib region 2230 of the mask frame 2210.

In accordance with the present embodiment, the membrane 2250 may define first openings 2252 that penetrate the grid region 2270 to partially expose the rib region 2230 of the mask frame 2210, and may include dielectric patterns 2290 disposed in the first openings 2252, respectively. For example, the dielectric patterns 2290 may be formed of a high-k material such as aluminum oxide (Al₂O₃), yttrium oxide (Y₂O₃), zirconium oxide (ZrO₂), hafnium oxide (HfO₂), lanthanum oxide (La₂O₃), barium oxide (BaO), or titanium oxide (TiO₂), and may be formed by physical vapor deposition, chemical vapor deposition, atomic layer deposition, or the like.

The upper electrodes 2040 may be disposed on the front surface of the substrate 2002 to correspond to the lower electrodes 2240 of the mask frame 2210, respectively, in the third direction DR3. In accordance with the present embodiment, the recesses 2292 may be provided at top surface portions of the dielectric patterns 2290, and the substrate 2002 may be disposed on the deposition mask 2200 such that the upper electrodes 2040 are inserted into the recesses 2292 of the dielectric patterns 2290, respectively.

In accordance with the present embodiment, when the substrate 2002 is disposed on the deposition mask 2200, the dielectric patterns 2290 may be disposed between the upper electrodes 2040 of the substrate 2002 and the lower electrodes 2240 of the deposition mask 2200. As a result, the electrostatic force between the upper electrodes 2040 of the substrate 2002 and the lower electrodes 2240 of the deposition mask 2200 may be increased, and accordingly, the deposition mask 2200 may be sufficiently brought into close contact with the front surface of the substrate 2002. In the present embodiment, the other elements except the dielectric patterns 2290 are substantially the same as those already described with reference to FIGS. 12 to 16, so that the description thereof is omitted.

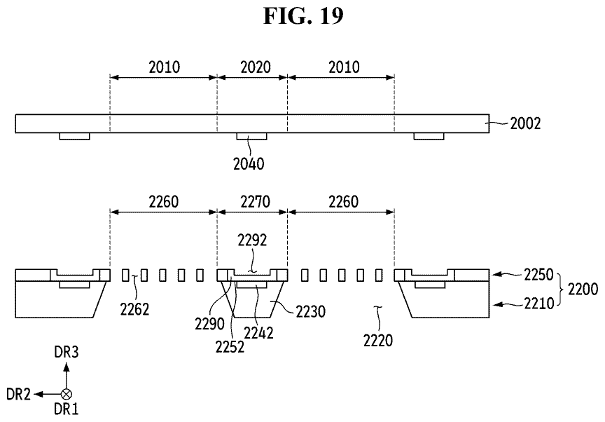

FIG. 19 is a schematic cross-sectional view illustrating a deposition mask according to still another embodiment of the present disclosure.

Referring to FIG. 19, the deposition mask 2200 according to still another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above the cell openings 2220, respectively, and the grid region 2270 disposed between the mask cell regions 2260.

In accordance with the present embodiment, the membrane 2250 may define the first openings 2252 that penetrate the grid region 2270 therein to partially expose the rib region 2230 of the mask frame 2210, and may include the dielectric patterns 2290 disposed in the first openings 2252, respectively. For example, the dielectric patterns 2290 may be formed of a high-k material such as aluminum oxide (Al₂O₃), yttrium oxide (Y₂O₃), zirconium oxide (ZrO₂), hafnium oxide (HfO₂), lanthanum oxide (La₂O₃), barium oxide (BaO), or titanium oxide (TiO₂), and may be formed by physical vapor deposition, chemical vapor deposition, atomic layer deposition, or the like.

The upper electrodes 2040 may be disposed on the front surface of the substrate 2002 to correspond to the dielectric patterns 2290, respectively, in the third direction DR3. In accordance with the present embodiment, the recesses 2292 may be defined at the top surface portions of the dielectric patterns 2290, and the substrate 2002 may be disposed on the deposition mask 2200 such that the upper electrodes 2040 are inserted into the recesses 2292 of the dielectric patterns 2290, respectively.

The mask frame 2210 may include the lower electrodes 2242 arranged to be spaced apart from the recesses 2292 in the thickness direction (i.e., DR3) of the mask frame 2210. In accordance with the present embodiment, the lower electrodes 2242 may be disposed in the top surface portions of the rib region 2230 of the mask frame 2210.

The lower electrodes 2242 of the mask frame 2210 may include a metal material. For example, the lower electrodes 2242 of the mask frame 2210 may include any one of copper (Cu), aluminum (Al), tungsten (W), molybdenum (Mo), chromium (Cr), gold (Au), titanium (Ti), nickel (Ni), and neodymium (Nd), or an alloy of any one of them, and may be formed by a physical vapor deposition process, a chemical vapor deposition process, an atomic layer deposition process, or the like.

For example, the lower electrodes 2242 of the mask frame 2210 may be formed by a damascene process. For another example, when the mask frame 2210 includes a silicon substrate (not shown) and an inorganic film (not shown) disposed on the silicon substrate, the lower electrodes 2242 may be disposed in the inorganic film on the silicon substrate by the damascene process. In this case, the lower electrodes 2242 and the inorganic film may have the same thickness, and the membrane 2250 may be disposed on the lower electrodes 2242 and the inorganic film.

In accordance with the present embodiment, the dielectric patterns 2290 of the membrane 2250 may be disposed on the lower electrodes 2242, respectively. In this case, in the deposition process, only the dielectric pattern 2290 of the membrane 2250 may be disposed between the lower electrodes 2242 of the mask frame 2210 and the upper electrodes 2040 of the substrate 2002. As a result, the electrostatic force between the upper electrodes 2040 of the substrate 2002 and the lower electrodes 2242 of the deposition mask 2200 may be greatly increased, so that the deposition mask 2200 may be brought into sufficiently close contact with the front surface of the substrate 2002. In the present embodiment, the other elements except the lower electrodes 2242 and the dielectric patterns 2290 are substantially the same as those already described with reference to FIGS. 12 to 16, so that the description thereof is omitted.

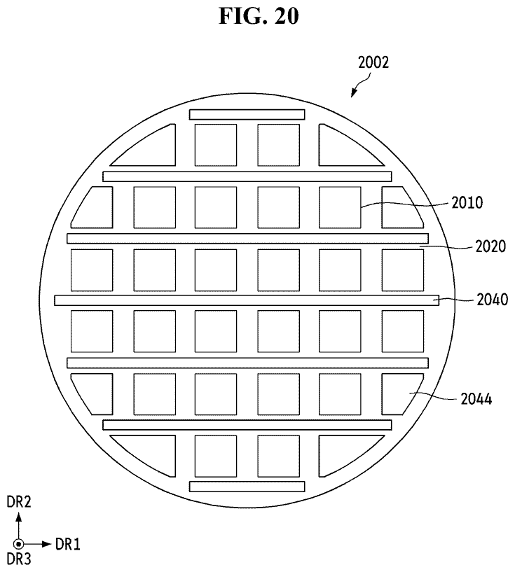

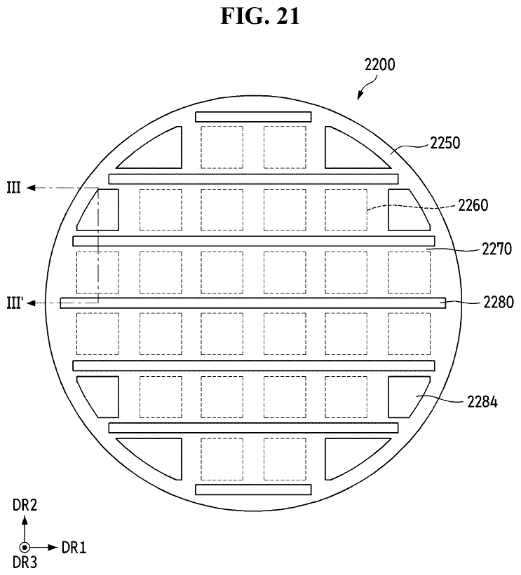

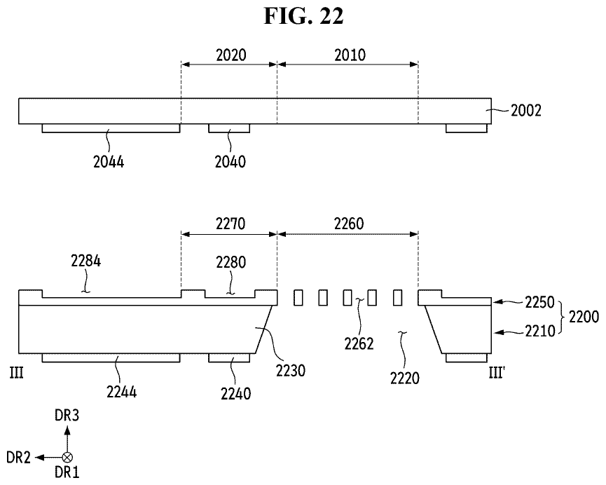

FIG. 20 is a schematic plan view illustrating another example of the substrate shown in FIG. 11. FIG. 21 is a schematic plan view illustrating a deposition mask according to still another embodiment of the present disclosure. FIG. 22 is a schematic cross-sectional view taken along line III-III′ shown in FIG. 21.

Referring to FIGS. 20 to 22, the deposition mask 2200 according to still another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above and overlapping the cell openings 2220, respectively, in a plan view, and the grid region 2270 surrounding the mask cell regions 2260.

The recesses 2280 may be defined at the surface portion of the membrane 2250. For example, the recesses 2280 may be defined at the top surface portions of the grid region 2270 of the membrane 2250. The mask frame 2210 may include lower electrodes 2240 arranged to be spaced apart from the recesses 2280 in the thickness direction of the mask frame 2210. For example, the lower electrodes 2240 may be disposed on the bottom surface of the rib region 2230 of the mask frame 2210 to correspond to the recesses 2280, respectively, in the third direction DR3. The upper electrodes 2040 corresponding to the recesses 2280, respectively, may be disposed on the front surface of the substrate 2002. In the deposition process, the substrate 2002 may be disposed on the deposition mask 2200, and the upper electrodes 2040 may be disposed in the recesses 2280, respectively.

In accordance with the present embodiment, as shown in FIG. 21, second recesses 2284 may be defined at top surface portions of an edge region of the membrane 2250, and the mask frame 2210 may include second lower electrodes 2244 arranged to be spaced apart from the second recesses 2284 in the thickness direction of the mask frame 2210. For example, as shown in FIG. 22, the second lower electrodes 2244 may correspond to the second recesses 2284, respectively, and may be disposed on the edge portions of the bottom surface of the mask frame 2210.

The substrate 2002 may include second upper electrodes 2044 corresponding to the second recesses 2284, respectively. For example, the second upper electrodes 2044 may be disposed on edge portions of the front surface of the substrate 2002. In particular, when the substrate 2002 is placed on the deposition mask 2200 in the deposition process, the second upper electrodes 2044 may be disposed in the second recesses 2284, respectively, so that the second lower electrodes 2244 and the second upper electrodes 2044 may correspond to each other in the third direction in the deposition process. As a result, the electrostatic force between the substrate 2002 and the deposition mask 2200 may be increased.

In accordance with the present embodiment, the second recesses 2284 and the recesses 2280 of the membrane 2250 may be formed simultaneously, and the second lower electrodes 2244 and the lower electrodes 2240 of the mask frame 2210 may be simultaneously formed using the same material. In addition, the second upper electrodes 2044 and the upper electrodes 2040 of the substrate 2002 may be formed of the same material as the anode electrodes AND and may be formed simultaneously with the anode electrodes

AND. In the present embodiment, the other elements except the second upper electrodes 2044, the second lower electrodes 2244, and the second recesses 2284 are substantially the same as those already described with reference to FIGS. 12 to 16, so that the description thereof is omitted.

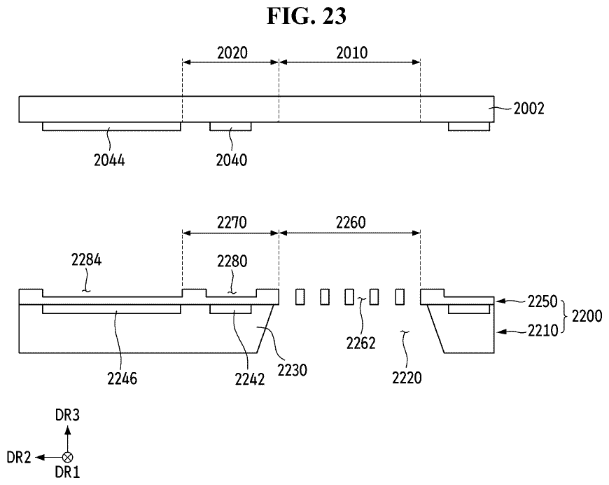

FIG. 23 is a schematic cross-sectional view illustrating a deposition mask according to still another embodiment of the present disclosure.

Referring to FIG. 23, the deposition mask 2200 according to still another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above and overlapping the cell openings 2220, respectively, in a plan view, and the grid region 2270 surrounding the mask cell regions 2260.

The recesses 2280 may be defined at the surface portion of the membrane 2250. For example, the recesses 2280 may be defined at the top surface portions of the grid region 2270 of the membrane 2250. The mask frame 2210 may include the lower electrodes 2242 arranged to be spaced apart from the recesses 2280 in the thickness direction (i.e., DR3) of the mask frame 2210. For example, the lower electrodes 2242 may be disposed in the top surface portions of the rib region 2230 of the mask frame 2210 to correspond to the recesses 2280, respectively, in the third direction DR3. The upper electrodes 2040 corresponding to the recesses 2280, respectively, may be disposed on the front surface of the substrate 2002. In the deposition process, the substrate 2002 may be disposed on the deposition mask 2200, and the upper electrodes 2040 may be disposed in the recesses 2280, respectively.

In accordance with the present embodiment, the second recesses 2284 may be defined at the top surface portions of the edge region of the membrane 2250, and the mask frame 2210 may include second lower electrodes 2246 arranged to be spaced apart from the second recesses 2284 in the thickness direction of the mask frame 2210. For example, the second lower electrodes 2246 may correspond to the second recesses 2284, respectively, and may be disposed in top surface portions of an edge region of the mask frame 2210, respectively.

The substrate 2002 may include second upper electrodes 2044 corresponding to the second recesses 2284, respectively. For example, the second upper electrodes 2044 may be disposed on edge portions of the front surface of the substrate 2002. In particular, when the substrate 2002 is placed on the deposition mask 2200 in the deposition process, the second upper electrodes 2044 may be disposed in the second recesses 2284, respectively, so that the second lower electrodes 2246 and the second upper electrodes 2044 may correspond to each other in the third direction in the deposition process. As a result, the electrostatic force between the substrate 2002 and the deposition mask 2200 may be increased.

In accordance with the present embodiment, the second recesses 2284 and the recesses 2280 of the membrane 2250 may be formed simultaneously, and the second lower electrodes 2246 and the lower electrodes 2242 of the mask frame 2210 may be simultaneously formed using the same material. In addition, the second upper electrodes 2044 and the upper electrodes 2040 of the substrate 2002 may be formed of the same material as the anode electrodes AND and may be formed simultaneously with the anode electrodes AND. In the present embodiment, the other elements except the second upper electrodes 2044, the second lower electrodes 2246, and the second recesses 2284 are substantially the same as those already described with reference to FIGS. 12 to 17, so that the description thereof is omitted.

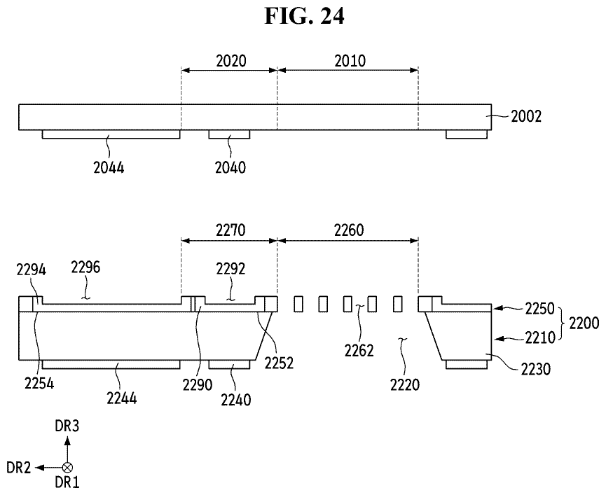

FIG. 24 is a schematic cross-sectional view illustrating a deposition mask according to still another embodiment of the present disclosure.

Referring to FIG. 24, the deposition mask 2200 according to still another embodiment of the present disclosure may include the mask frame 2210 and the membrane 2250. The mask frame 2210 may define the cell openings 2220 therein, and may include the rib region 2230 defining the cell openings 2220. The membrane 2250 may include the mask cell regions 2260 disposed above the cell openings 2220, respectively, and the grid region 2270 surrounding the mask cell regions 2260.

The membrane 2250 may define the first openings 2252 that penetrate the grid region 2270 to partially expose the rib region 2230 of the mask frame 2210, and the dielectric patterns 2290 may be disposed in the first openings 2252, respectively. The recesses 2292 may be defined at the surface portions of the dielectric patterns 2290, respectively, and the mask frame 2210 may include the lower electrodes 2240 arranged to be spaced apart from the recesses 2292 in the thickness direction (i.e., DR3) of the mask frame 2210. For example, the lower electrodes 2240 may be disposed on the bottom surface of the rib region 2230 of the mask frame 2210 to correspond to the recesses 2292, respectively, in the third direction DR3. The upper electrodes 2040 corresponding to the recesses 2292, respectively, may be disposed on the front surface of the substrate 2002. In the deposition process, the substrate 2002 may be disposed on the deposition mask 2200, and the upper electrodes 2040 may be disposed in the recesses 2292, respectively.

In accordance with the present embodiment, the membrane 2250 may define second openings 2254 that penetrate edge portions of the membrane 2250 to partially expose edge portions of the mask frame 2210, and second dielectric patterns 2294 may be disposed in the second openings 2254, respectively. Second recesses 2296 may be defined at top surface portions of the second dielectric patterns 2294, and the mask frame 2210 may include the second lower electrodes 2244 arranged to be spaced apart from the second recesses 2296 in the thickness direction of the mask frame 2210. For example, the second lower electrodes 2244 may correspond to the second recesses 2296, respectively, and may be disposed on the edge portions of the bottom surface of the mask frame 2210.

The substrate 2002 may include the second upper electrodes 2044 corresponding to the second recesses 2296, respectively. For example, the second upper electrodes 2044 may be disposed on the edge portions of the front surface of the substrate 2002. In particular, when the substrate 2002 is placed on the deposition mask 2200 in the deposition process, the second upper electrodes 2044 may be disposed in the second recesses 2296, respectively, so that the second lower electrodes 2244 and the second upper electrodes 2044 may correspond to each other in the third direction in the deposition process. As a result, the electrostatic force between the substrate 2002 and the deposition mask 2200 may be increased.

In accordance with the present embodiment, the second dielectric patterns 2294 and the dielectric patterns 2290 of the membrane 2250 may be simultaneously formed using the same material, and the second lower electrodes 2244 and the lower electrodes 2240 of the mask frame 2210 may be simultaneously formed using the same material. In addition, the second upper electrodes 2044 and the upper electrodes 2040 of the substrate 2002 may be formed of the same material as the anode electrodes AND and may be formed simultaneously with the anode electrodes AND. In the present embodiment, the other elements except the second upper electrodes 2044, the second lower electrodes 2244, and the second dielectric patterns 2294 are substantially the same as those already described with reference to FIGS. 12 to 16 and 18, so that the description thereof is omitted.

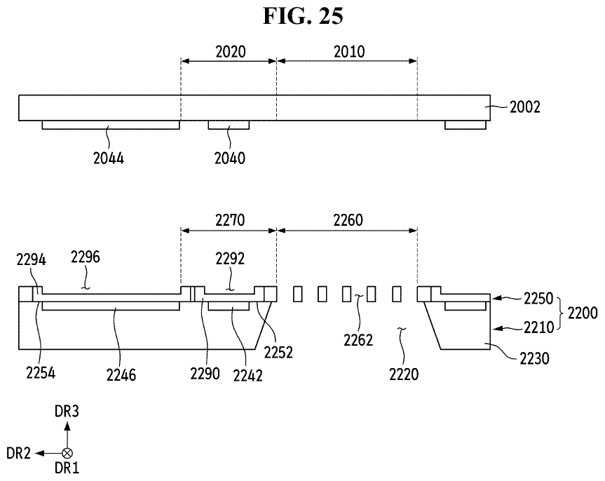

FIG. 25 is a schematic cross-sectional view illustrating a deposition mask according to still another embodiment of the present disclosure.

Referring to FIG. 25, the deposition mask 2200 according to still another embodiment of the present disclosure may include the mask frame 2210 and the membrane 2250. The mask frame 2210 may have the cell openings 2220 therein, and may include the rib region 2230 defining the cell openings 2220. The membrane 2250 may include the mask cell regions 2260 disposed above and overlapping the cell openings 2220, respectively, in a plan view, and the grid region 2270 surrounding the mask cell region 2260.

The membrane 2250 may define the first openings 2252 that penetrate the grid region 2270 to partially expose the rib region 2230 of the mask frame 2210, and the dielectric patterns 2290 may be disposed in the first openings 2252, respectively. The recesses 2292 may be defined at the surface portions of the dielectric patterns 2290, respectively, and the mask frame 2210 may include the lower electrodes 2242 arranged to be spaced apart from the recesses 2292 in the thickness direction of the mask frame 2210. For example, the lower electrodes 2242 may disposed in the top surface portions of the rib region 2230 of the mask frame 2210, respectively, to correspond to the recesses 2292 in the third direction DR3, respectively, and the dielectric patterns 2290 of the membrane 2250 may be disposed on the lower electrodes 2242, respectively. The upper electrodes 2040 corresponding to the recesses 2292, respectively, may be disposed on the front surface of the substrate 2002. In the deposition process, the substrate 2002 may be disposed on the deposition mask 2200, and the upper electrodes 2040 may be disposed in the recesses 2292, respectively.

In accordance with the present embodiment, the membrane 2250 may define the second openings 2254 that penetrate the edge portions of the membrane 2250 to partially expose the edge portions of the mask frame 2210, and the second dielectric patterns 2294 may be disposed in the second openings 2254, respectively. Second recesses 2296 may be defined at the top surface portions of the second dielectric patterns 2294, and the mask frame 2210 may include the second lower electrodes 2246 arranged to be spaced apart from the second recesses 2296 in the thickness direction (i.e., DR3) of the mask frame 2210. For example, the second lower electrodes 2246 may correspond to the second recesses 2296, respectively, and may be disposed in the top surface portions of the edge region of the mask frame 2210, respectively. In this case, the second dielectric patterns 2294 may be disposed on the second lower electrodes 2246, respectively.

The substrate 2002 may include the second upper electrodes 2044 corresponding to the second recesses 2296, respectively. For example, the second upper electrodes 2044 may be disposed on the edge portions of the front surface of the substrate 2002. In particular, when the substrate 2002 is placed on the deposition mask 2200 in the deposition process, the second upper electrodes 2044 may be disposed in the second recesses 2296, respectively, so that the second lower electrodes 2246 and the second upper electrodes 2044 may correspond to each other in the third direction in the deposition process. As a result, the electrostatic force between the substrate 2002 and the deposition mask 2200 may be increased.

In accordance with the present embodiment, the second dielectric patterns 2294 and the dielectric patterns 2290 of the membrane 2250 may be simultaneously formed using the same material, and the second lower electrodes 2246 and the lower electrodes 2242 of the mask frame 2210 may be simultaneously formed using the same material. In addition, the second upper electrodes 2044 and the upper electrodes 2040 of the substrate 2002 may be formed of the same material as the anode electrodes AND and may be formed simultaneously with the anode electrodes AND. In the present embodiment, the other elements except the second upper electrodes 2044, the second lower electrodes 2246, and the second dielectric patterns 2294 are substantially the same as those already described with reference to FIGS. 12 to 16 and 19, so that the description thereof is omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask frame defining cell openings therein; and
a membrane comprising mask cell regions disposed above and overlapping the cell openings, respectively, and a grid region disposed between the mask cell regions,
wherein a first recess is defined at a surface portion of the membrane, and
the mask frame comprises a rib region defining the cell openings and a first lower electrode disposed to be spaced apart from the first recess in a thickness direction of the mask frame.

2. The deposition mask of claim 1, wherein the first recess is defined at a top surface portion of the grid region of the membrane, and
the first lower electrode is disposed on a bottom surface of the rib region of the mask frame or in a top surface portion of the rib region of the mask frame.

3. The deposition mask of claim 1, wherein the membrane defines a first opening penetrating the grid region to partially expose the rib region of the mask frame, and further comprises a dielectric pattern disposed in the first opening.

4. The deposition mask of claim 3, wherein the first recess is defined in a top surface portion of the dielectric pattern.

5. The deposition mask of claim 3, wherein the first lower electrode is disposed on a bottom surface of the rib region of the mask frame.

6. The deposition mask of claim 3, wherein the first lower electrode is disposed in a top surface portion of the rib region of the mask frame, and
the dielectric pattern is disposed on the first lower electrode.

7. The deposition mask of claim 1, wherein the first recess is defined at a top surface portion of the grid region of the membrane, and
a second recess different from the first recess is defined at a top surface portion of an edge region of the membrane.

8. The deposition mask of claim 7, wherein the mask frame further comprises a second lower electrode different from the first lower electrode and disposed to be spaced apart from the second recess in the thickness direction of the mask frame.

9. A deposition apparatus comprising:
a deposition source;
a deposition mask disposed above the deposition source; and
an electrostatic chuck configured to support a substrate such that the substrate is disposed on the deposition mask,
wherein a first upper electrode is disposed on the substrate,
the deposition mask comprises a mask frame defining cell openings therein, and a membrane comprising mask cell regions disposed above and overlapping the cell openings, respectively, and a grid region disposed between the mask cell regions, and
the mask frame comprises a rib region defining the cell openings and a first lower electrode disposed to be spaced apart from the first upper electrode in a thickness direction of the mask frame.

10. The deposition apparatus of claim 9, wherein a first recess is defined at a top surface portion of the grid region of the membrane, and
the first upper electrode is configured to be disposed in the first recess.

11. The deposition apparatus of claim 10, wherein the first upper electrode has a thickness equal to or greater than a depth of the first recess so as to be in contact with a bottom surface of the first recess.

12. The deposition apparatus of claim 10, wherein the first lower electrode is disposed on a bottom surface of the rib region of the mask frame or in a top surface portion of the rib region of the mask frame.

13. The deposition apparatus of claim 9, wherein the membrane defines a first opening penetrating the grid region to partially expose the rib region of the mask frame, and further comprises a dielectric pattern disposed in the first opening.

14. The deposition apparatus of claim 13, wherein a first recess is defined in a top surface portion of the dielectric pattern, and
the first upper electrode is configured to be disposed in the first recess.

15. The deposition apparatus of claim 13, wherein the first lower electrode is disposed in a top surface portion of the rib region of the mask frame, and the dielectric pattern is disposed on the first lower electrode.

16. The deposition apparatus of claim 9, wherein the substrate comprises display cell regions disposed on the mask cell regions, respectively, and a scribe lane region disposed between the display cell regions, and
the first upper electrode is disposed on the scribe lane region.

17. The deposition apparatus of claim 16, wherein anode electrodes are disposed on the display cell regions, and
the first upper electrode is made of a same material as the anode electrodes.

18. The deposition apparatus of claim 16, wherein a second upper electrode different from the first upper electrode is disposed on an edge region of the substrate, and
the mask frame further comprises a second lower electrode different from the first lower electrode and disposed to be spaced apart from the second upper electrode in the thickness direction of the mask frame.

19. The deposition apparatus of claim 18, wherein a second recess different from the first recess is defined at a top surface portion of an edge region of the membrane, and
the second upper electrode is configured to be disposed in the second recess.

20. An electronic device comprising a display panel,
wherein the display panel comprises a substrate and a plurality of light-emitting layers formed on the substrate by using a deposition mask, and
the deposition mask comprises:
a mask frame defining cell openings therein; and
a membrane comprising mask cell regions disposed above and overlapping the cell openings, respectively, and a grid region disposed between the mask cell regions,
wherein a first recess is defined at a surface portion of the membrane, and
the mask frame comprises a rib region defining the cell openings and a first lower electrode disposed to be spaced apart from the first recess in a thickness direction of the mask frame.
